(19) United States
(12) Patent Application Publication
(10) Pub. No.: US 2025/0299956 A1
(43) Pub. Date: Sep. 25, 2025

(54) SEMICONDUCTOR DEVICE AND METHOD OF MANUFACTURING THE SAME

(71) Applicant: Renesas Electronics Corporation, Tokyo (JP)

(72) Inventor: Koji NIIYAMA, Tokyo (JP)

(21) Appl. No.: 19/010,640

(22) Filed: Jan. 6, 2025

(30) Foreign Application Priority Data
Mar. 25, 2024 (JP) 2024-047753

(51) Int. Cl. H01L 21/268; H01L 21/30; H10D 62/10; H10D 62/13; H10D 62/60

(52) U.S. Cl. CPC H01L 21/268; H01L 21/3003; H10D 62/124; H10D 62/60; H10D 62/141

(57) ABSTRACT

A method of manufacturing a semiconductor device according to the present disclosure includes: introducing an impurity having a first conductivity type from an upper surface of a semiconductor substrate having the upper surface and a lower surface; forming a metal layer on the upper surface; introducing hydrogen from the lower surface and forming a first semiconductor layer; performing first heat treatment on the semiconductor substrate, and donating the hydrogen introduced into the first semiconductor layer; introducing from the lower surface an impurity of a second conductivity type opposite to the first conductivity type, and forming a second semiconductor layer at a position shallower than a position of the first semiconductor layer; and performing second heat treatment on the semiconductor substrate at a temperature higher than a temperature of the first heat treatment, and applying the second conductivity type to the second semiconductor layer.

### CROSS-REFERENCE TO RELATED APPLICATIONS

The disclosure of Japanese Patent Application No. 2024-047753 filed on Mar. 25, 2024 including the specification, drawings and abstract is incorporated herein by reference in its entirety.

### BACKGROUND

The present disclosure relates to a semiconductor device and a method of manufacturing the semiconductor device, and, more particularly, to a method of manufacturing a Fast Recovery Diode (FRD) and an Insulated Gate Bipolar Transistor (IGBT).

A Fast Recovery Diode (FRD) is a diode obtained by applying measures for reducing a reverse recovery time to a diode having a pn junction. The FRD has been made for the purpose of rectifying a high frequency such as several tens of kHz or several hundreds of kHz used in a switching power supply or the like, and has a feature that the reverse recovery time is two to three digits shorter than that of a general rectifier diode.

Furthermore, an Insulated Gate Bipolar Transistor (IGBT) refers to a transistor that has an input unit having a Metal-Oxide-Semiconductor (MOS) structure and an output unit having a bipolar structure. The IGBT has a feature of a MOS field effect transistor having a high input impedance and a high switching speed, and a feature of a bipolar transistor having a low saturation voltage.

The FRD and the IGBT are widely used as power devices such as motors and batteries.

There are disclosed techniques listed below.
[Patent Document 1] Japanese Unexamined Patent Application Publication No. 2005-72157
[Patent Document 2] Japanese Unexamined Patent Application Publication No. 2022-73497

Patent Document 1 discloses a power conversion device including a transistor that performs a switching operation, and a diode that is connected in parallel to the transistor. By using as a transistor a bipolar transistor containing Ge of a predetermined concentration distribution, it is possible to provide a highly efficient AC/DC converter or the like.

### SUMMARY

Increase of the speed and improvement of operation guarantee temperatures of power devices caused by market growth of electric vehicles are tasks that need to be addressed at all times.

Other tasks and new features will be made more apparent from the description and the accompanying drawings of this description.

A method of manufacturing a semiconductor device according to the present disclosure includes: introducing an impurity having a first conductivity type from an upper surface of a semiconductor substrate having the upper surface and a lower surface; forming a metal layer on the upper surface; introducing hydrogen from the lower surface and forming a first semiconductor layer; performing first heat treatment on the semiconductor substrate, and donating the hydrogen introduced into the first semiconductor layer; introducing from the lower surface an impurity of a second conductivity type opposite to the first conductivity type, and forming a second semiconductor layer at a position shallower than a position of the first semiconductor layer; and performing second heat treatment on the semiconductor substrate at a temperature higher than a temperature of the first heat treatment, and applying the second conductivity type to the second semiconductor layer.

A semiconductor device according to the present disclosure includes: a semiconductor substrate that has an upper surface and a lower surface; a metal layer that is formed on the upper surface; an impurity region that is formed on a side of the upper surface and has a first conductivity type; a first semiconductor layer that is formed on a side of the lower surface, has a first thickness in a direction perpendicular to the lower surface, and contains donated hydrogen; and a second semiconductor layer that is formed closer to the side of the lower surface than the first semiconductor layer, contains an impurity of a second conductivity type opposite to the first conductivity type, and has a second thickness smaller than the first thickness, the first semiconductor layer includes a first region that has a maximum value in a carrier concentration distribution in the first semiconductor layer, the second semiconductor layer includes a second region that has a carrier concentration distribution lower than the carrier concentration distribution of the first semiconductor layer, and when the lower surface is set as a reference surface, the first region is located at a position deeper than a position of the second region.

According to the present disclosure, it is possible to provide a semiconductor device that increases a speed and improves an operation guarantee temperature, and a method of manufacturing the semiconductor device.

### BRIEF DESCRIPTION OF THE DRAWINGS

FIG. 1 is a cross-sectional view of a semiconductor device according to a first embodiment.

FIGS. 2A to 2E are views for explaining a method of manufacturing the semiconductor device according to the first embodiment.

FIGS. 3A and 3B are views for explaining a carrier concentration distribution of the semiconductor device according to the first embodiment.

FIG. 4 is a view for explaining a carrier concentration distribution of a semiconductor device according to a comparative example.

FIGS. 5A and 5B are views for explaining defects caused by introduction of impurities in the semiconductor device according to the first embodiment.

FIG. 6 is a view for explaining the method of manufacturing the semiconductor device according to the first embodiment.

FIGS. 7A and 7B are views for explaining recovery of defects in a semiconductor device according to a second embodiment.

FIGS. 8A to 8C are views for explaining recovery of defects in a semiconductor device according to a third embodiment.

FIG. 9 is a view for explaining defects caused by introduction of impurities in the semiconductor device according to the third embodiment.

FIG. 10 is a view for explaining recovery of defects in a semiconductor device according to a fourth embodiment.

### DETAILED DESCRIPTION

Hereinafter, embodiments of the present disclosure will be described in detail with reference to the drawings. In the description and the drawings, the same components or corresponding components will be assigned the same reference numerals, and redundant description will be omitted. In the drawings, components may be omitted or simplified for convenience of description. Furthermore, at least part of each embodiment may be arbitrarily combined with each other.

The impurity concentration of each component included in a semiconductor device according to the present disclosure refers to a peak value in a measured region of the component. Furthermore, the expression “approximately equal” in a case where the impurity concentrations of two components are compared does not necessarily mean only that the impurity concentrations completely match with each other. Even when the impurity concentrations of the two components are different due to manufacturing variations, if the setting values of the impurity concentrations of the two components are the same, the impurity concentrations of the two components are considered to be the same.

### First Embodiment

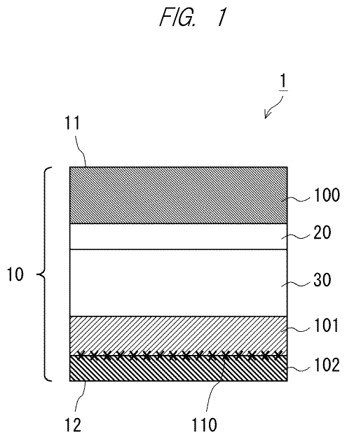

FIG. 1 is a cross-sectional view of a semiconductor substrate 10 (n-type Si substrate) in a semiconductor device 1. The semiconductor device 1 includes a semiconductor substrate 10 that has an upper surface 11 and a lower surface 12, and a plurality of regions that are formed in the semiconductor substrate 10 and on an upper surface 11 and a lower surface 12 of the semiconductor substrate.

A metal layer 100 is formed on the upper surface 11 of the semiconductor substrate 10, and an impurity region 20 is formed under the metal layer 100. On the lower surface 12 of the semiconductor substrate 10, a second semiconductor layer 102, a first semiconductor layer 101, and a third semiconductor layer 103 are formed in order from the bottom. Furthermore, defects 110 caused by introduction of impurities exist between the second semiconductor layer 102 and the first semiconductor layer 101.

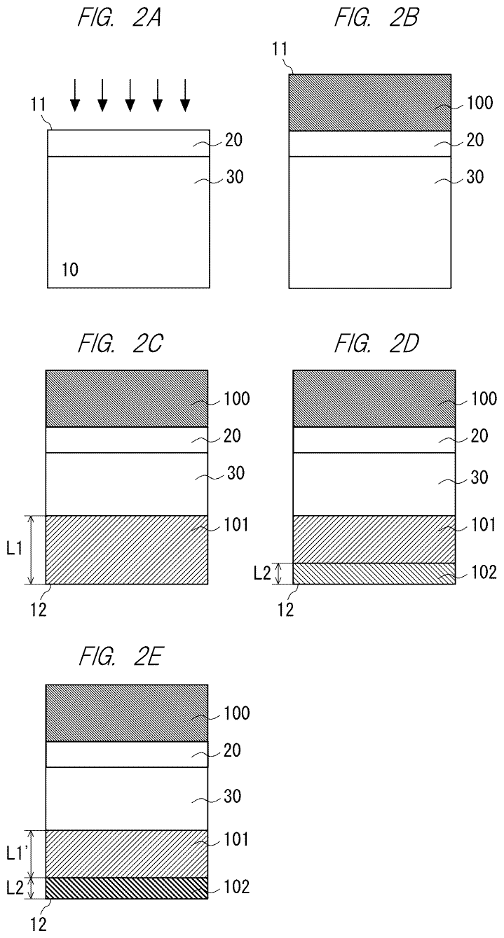

Hereinafter, each element constituting the semiconductor device 1 and a method of manufacturing the element will be described with reference to FIG. 2.

First, impurities having a first conductivity type are introduced from the upper surface 11 of the semiconductor substrate 10 (see FIG. 2A). Thus, the impurity region 20 and the region 30 (n-type Si substrate) having the first conductivity type are formed on the upper surface 11 of the semiconductor substrate 10. In the semiconductor device 1, the impurity region 20 functions as an anode layer, and the region 30 functions as a drift layer. For ease of understanding, the present embodiment will be described using a specific example where B (boron) is introduced into the semiconductor substrate 10 that is an n-type (second conductivity type) silicon substrate to form a p-type (first conductivity type) impurity region on an upper surface 11 of the semiconductor substrate 10.

Next, the metal layer 100 is formed on the upper surface 11 of the semiconductor substrate 10 (see FIG. 2B). The metal layer 100 is formed by using a film forming method such as sputtering of a metal material such as aluminum (Al). The metal layer 100 functions as an anode electrode in the semiconductor device 1.

Next, hydrogen is introduced from the lower surface 12 of the semiconductor substrate 10 (see FIG. 2C). Thus, the first semiconductor layer 101 having a first thickness L1 in a direction perpendicular to the lower surface 12 is formed. The hydrogen is introduced using a method such as ion implantation or ion doping.

After the hydrogen is introduced, first heat treatment is performed on the semiconductor substrate 10 to donor the hydrogen introduced into the first 101 semiconductor layer (not illustrated). Thus, the first semiconductor layer 101 functions as an n-type donor layer that has an impurity concentration higher than that of the semiconductor substrate 10. The first heat treatment is preferably performed at 350 to 400° C. (350 to 400 degrees Celsius and, for example, 350 degrees Celsius) for about one hour using a heating furnace or the like (see Patent Document 2).

Next, impurities of a second conductivity type that is a conductivity type opposite to the first conductivity type are introduced from the lower surface 12 of the semiconductor substrate 10 (see FIG. 2D). Thus, the second semiconductor layer 102 having a second thickness L2 smaller than the first thickness L1 in the direction perpendicular to the lower surface 12 is formed at a position shallower than that of the first semiconductor layer 101, that is, at a position close to the lower surface 12 of the semiconductor substrate 10. In the present embodiment, the second semiconductor layer 102 is formed by introducing phosphorus (P). Note that the defects 110 caused by introduction of the impurities illustrated in FIG. 1 exist at a time of this process, yet become complicated defects if illustrated and therefore are omitted in FIG. 2D. Details of the defects 110 caused by introduction of the impurities will be described later.

After impurities of the second conductivity type are introduced, second heat treatment is performed on the semiconductor substrate 10 to activate the impurities of the second conductivity type, and apply the second conductivity type to the second semiconductor layer 102 (see FIG. 2E). In the present embodiment, as a result, the second semiconductor layer 102 is applied the n-type (second conductivity type), and functions as a field stop layer in the semiconductor device 1. The second heat treatment is preferably performed at a higher temperature than that of the first heat treatment, and is performed at a higher temperature than that of the first heat treatment using, for example, laser light irradiation or the like. The heat treatment that uses laser light irradiation is a local heat load, so that it is possible to suppress desorption of hydrogen in a region that does not reach an irradiation depth of the laser light.

Since the hydrogen contained in a region close to the lower surface 12 of the semiconductor substrate 10 in the first semiconductor layer 101 is desorbed by the second heat treatment, the thickness of the first semiconductor layer 101 after the second heat treatment decreases to L1′ (≈L1−L2 where L1′>L2 holds).

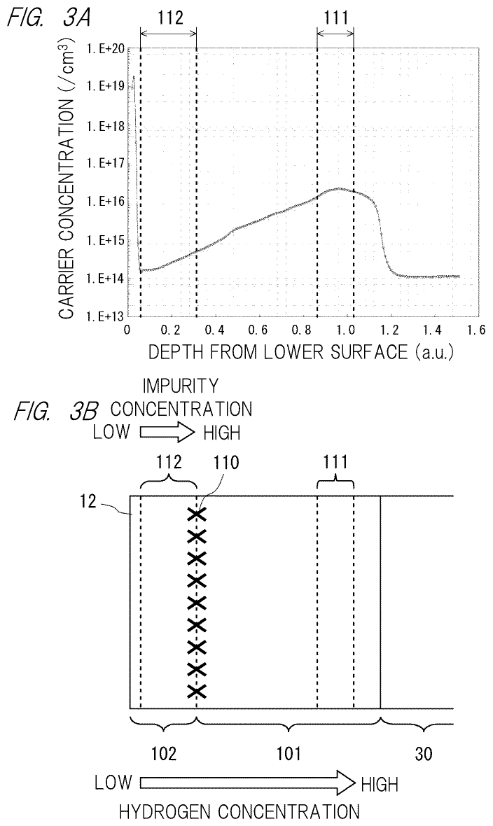

A distribution of hydrogen donors in the semiconductor substrate 10 after the second heat treatment is performed will be described with reference to FIG. 3A. FIG. 3A illustrates a carrier concentration distribution by a Spreading Resistance Profiling (SRP) method in the depth direction in a case where the lower surface 12 of the semiconductor substrate 10 is set as a reference surface. Note that the horizontal axis indicating the depth indicates that the depth at which a first region 111 in which the carrier concentration comes to a peak is located is normalized as one.

It can be found that the carrier concentration distribution inclines from the first region 111 in which the carrier concentration distribution takes a maximum value toward the lower surface 12 of the semiconductor substrate 10. In other words, the carrier concentration distribution of the first semiconductor layer 101 after the second heat treatment has a gradient of the carrier concentration that increases toward the depth direction when the lower surface 12 is set as the reference surface.

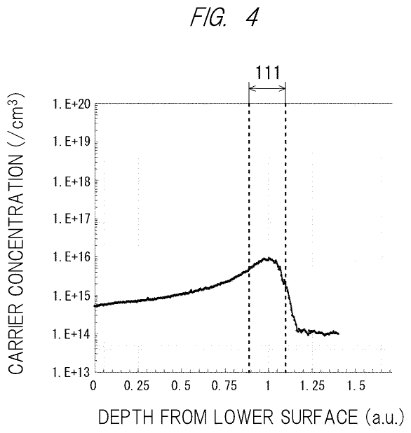

FIG. 4 illustrates as a comparative example a distribution of the carrier concentration of the semiconductor substrate for which hydrogen has been introduced and the first heat treatment has been performed, that is, for which the impurities of the second conductivity type are not introduced and the second heat treatment is not performed. The carrier concentration distribution in a region closer to the lower surface 12 of the semiconductor substrate 10 than the first region 111 in which the carrier concentration comes to the peak is flat as compared with the carrier concentration distribution in FIG. 3A.

Comparison between FIG. 3A and FIG. 4 shows that the hydrogen contained in a region close to the lower surface 12 of the semiconductor substrate 10 is desorbed by performing the second heat treatment. A region (second region 112) in which this inclination is steep, that is, a region that has a carrier concentration distribution lower than that of the first semiconductor layer 101 is defined as a hydrogen desorption region. In other words, a minimum value of the hydrogen concentration distribution in the second region 112 is smaller than a setting value of a hydrogen dose amount at the time of introduction of hydrogen.

FIG. 3B illustrates that the first semiconductor layer 101, the second semiconductor layer 102, and the region 30 in which no impurity is introduced in the semiconductor substrate 10 are fitted to the carrier concentration distribution illustrated in FIG. 3A. The first region 111 in which the carrier concentration comes to the peak is formed in the first semiconductor layer 101, and the second region 112 that is the hydrogen desorption region is formed in the second semiconductor layer 102.

Furthermore, although not illustrated in FIG. 3A, an inclination is observed from the concentration of the impurities of the second conductivity type. There are the many defects 110 caused by introduction of impurities in a peak region of the concentration of the impurities of this second conductivity type.

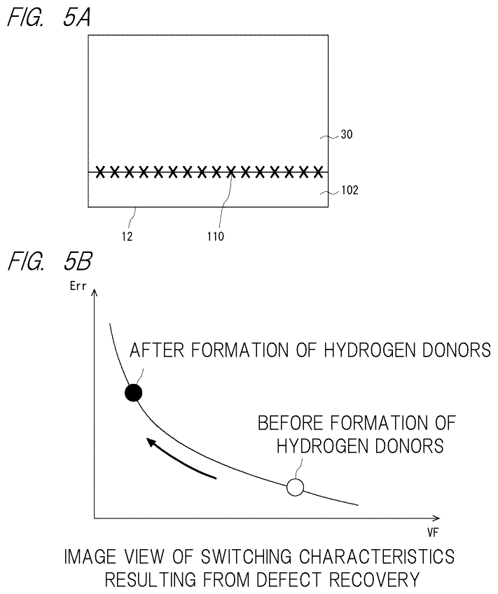

In the semiconductor device 1 according to the present disclosure, the many defects 110 caused by introduction of impurities are made between the second semiconductor layer 102 and the first semiconductor layer 101 to reduce switching loss and facilitate adjustment to increase a speed. This mechanism will be described with reference to FIG. 5.

FIG. 5A is a cross-sectional view of a semiconductor substrate for which impurities (phosphorus) of the second conductivity type have been introduced and the second heat treatment has been performed, that is, for which hydrogen is not introduced and the first heat treatment is not performed. Accordingly, in the semiconductor substrate, only the second semiconductor layer 102 and the region 30 into which no impurity is introduced are formed, and the defects 110 caused by introduction of the impurities is formed between the second semiconductor layer 102 and the region 30.

Studies conducted by the inventor of the present invention have confirmed that, when energy of introduction of impurities of the second conductivity type is increased, switching loss of the semiconductor device is reduced. Since, when the energy of introduction of impurities of the second conductivity type is increased, the defects 110 caused by introduction of impurities increase, it is found that it is effective to increase the defects 110 caused by introduction of impurities to reduce the switching loss of the semiconductor device.

Furthermore, since an operation temperature and the switching loss of the semiconductor device have a substantially proportional relationship, reducing the switching loss leads to improvement of the operation guarantee temperature.

On the other hand, although it is effective to reduce the thickness of the semiconductor substrate to improve electrical characteristics of the semiconductor device, there is a problem that ringing is likely to occur when the thickness of the semiconductor substrate is reduced. To suppress this ringing, it is effective to form hydrogen donors.

Accordingly, to achieve both of reduction of the switching loss of the semiconductor device and suppression of ringing, it is necessary to satisfy both of the increase of the defects 110 caused by introduction of impurities and formation of hydrogen donors.

The inventor of the present invention has found a problem that, when hydrogen donors are formed after formation of the defects 110 caused by introduction of impurities, part of the defects 110 are recovered by a hydrogen donor formation process. FIG. 5B illustrates an image view of fluctuation of switching characteristics caused by defect recovery. The vertical axis indicates switching loss Err, and the horizontal axis indicates a forward voltage VF. When defects are recovered, while the operating voltage decreases, the switching loss tends to increase.

As indicated by the method of manufacturing the semiconductor device according to the present disclosure, the inventor of the present invention has overcome this problem by forming the defects 110 caused by introduction of impurities after formation of hydrogen donors.

In this way, the method of manufacturing the semiconductor device according to the present disclosure can increase a speed and improve the operation guarantee temperature.

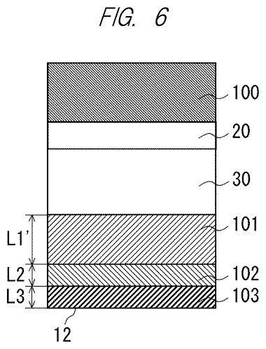

Furthermore, the above-described method of manufacturing the semiconductor device is a method of manufacturing an FRD. When an IGBT is manufactured, impurities of the first conductivity type are introduced from the lower surface 12 of the semiconductor substrate 10 before the second heat treatment (see FIG. 2D) (see FIG. 6). Thus, the third semiconductor layer 103 having a third thickness L3 in the direction perpendicular to the lower surface 12 is formed at a position shallower than that of the second semiconductor layer 102, that is, a position close to the lower surface 12 of the semiconductor substrate 10. In the present embodiment, the third semiconductor layer 103 is formed by introducing B (boron). The third semiconductor layer 103 is applied a p-type (first conductivity type) by the subsequent second heat treatment, and functions as a collector layer in the semiconductor device 1 that is the IGBT.

The method of manufacturing the semiconductor device according to the present disclosure can form the second semiconductor layer 102 and the third semiconductor layer 103 after formation of the hydrogen donors, so that it is easy to adjust the characteristics of the field stop layer and the collector layer, and it is possible to increase the speed and improve the operation guarantee temperature.

### Second Embodiment

As for a modification of the method of manufacturing the semiconductor device according to the first embodiment, the present embodiment will describe a case where an irradiation depth of laser light used for the second heat treatment in particular is made larger than that in the first embodiment. Note that description of components similar to those of the first embodiment will be omitted.

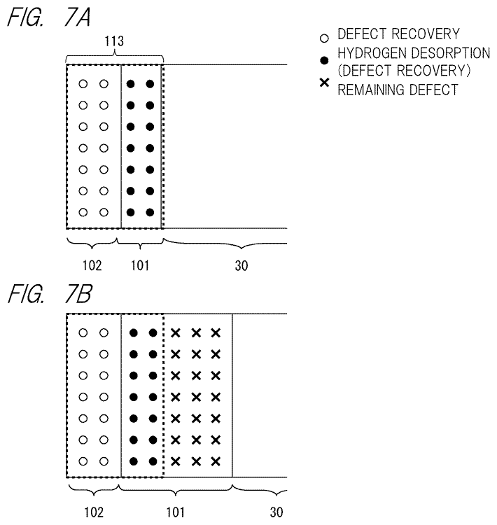

FIG. 7A illustrates an example where a laser light irradiation condition of the second heat treatment is changed, and the irradiation depth of the laser light reaches a region in which hydrogen donors are formed. White circles in FIG. 7A indicate recovery of defects resulting from laser light irradiation, and black circles indicate recovery of the defects resulting from desorption of hydrogen by laser light irradiation. Accordingly, a third region 113 surrounded by a dotted line indicates a defect recovery region in which the defects have been recovered by laser light irradiation, and the third region 113 is formed on the side of a lower surface 12 of a semiconductor substrate 10.

FIG. 7B illustrates an example where laser light irradiation under the same condition as that in FIG. 7A is performed in a state where hydrogen donors are formed at deeper positions as compared with the first embodiment. White circles and black circles in FIG. 7B are similar to those in FIG. 7A, and cross marks indicate that defects are not recovered by laser light irradiation, that is, the defects remain. By applying these formation of the hydrogen donors and laser light irradiation, it is possible to expect an effect of suppressing extension of a depletion layer caused by the formation of the hydrogen donors.

### Third Embodiment

As for a modification of the method of manufacturing the semiconductor device according to the first embodiment, the present embodiment will describe a case where an irradiation depth of laser light used for second heat treatment in particular is changed. Note that description of components similar to those in the first and second embodiments will be omitted.

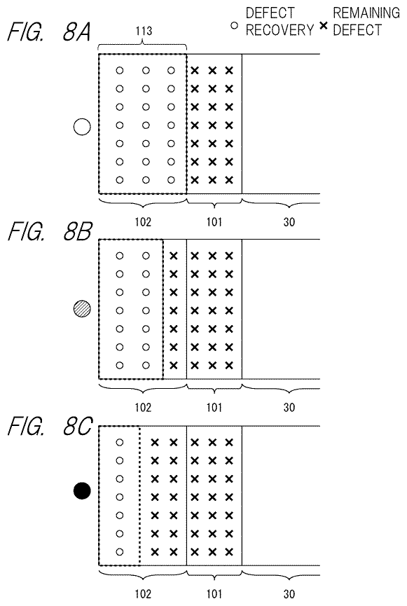

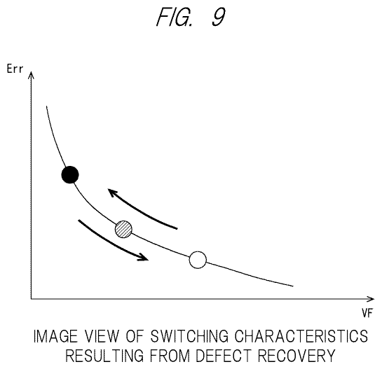

The irradiation depth of laser light can be controlled by changing the wavelength of the laser light. FIG. 8A is similar to the manufacturing method described in the first embodiment, and illustrates an example where the irradiation depth of the laser light is adjusted to the depth at which a second semiconductor layer 102 is formed, and a third region 113 that is a crystal recovery region is formed. As described in the first embodiment, this manufacturing method has an advantage that switching loss is little (see a white circle in FIG. 9).

FIG. 8B illustrates an example where the irradiation depth of the laser light is adjusted so as to reach the middle of the second semiconductor layer 102, and the third region 113 that is the crystal recovery region is formed. This manufacturing method keeps the balance between switching loss and an operating voltage (see a hatched circle in FIG. 9).

FIG. 8C illustrates that the irradiation depth of the laser light is further made smaller than that in FIG. 8B. This manufacturing method has an advantage that it is possible to reduce the operating voltage (see a black circle in FIG. 9).

As described above, by changing the irradiation depth of the laser light, it is possible to flexibly support specifications required for the semiconductor device.

### Fourth Embodiment

As for a modification of the method of manufacturing the semiconductor device according to the first embodiment, the present embodiment will describe a case where a semiconductor device is an IGBT in particular. As described in the first embodiment, when the IGBT is manufactured, a third semiconductor layer 103 is formed by introducing impurities of the first conductivity type from a lower surface 12 of a semiconductor substrate 10 before the second heat treatment is performed.

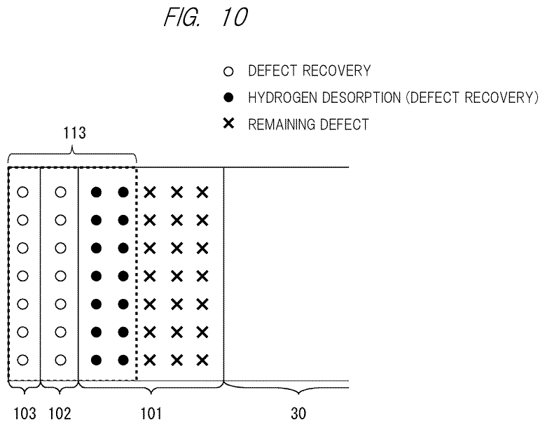

FIG. 10 illustrates an example where defects formed in the third semiconductor layer 103 are recovered by laser light irradiation of the second heat treatment. White circles, black circles, and crosses in the drawing are similar to those in the second embodiment. A third region that is the defect recovery region is also formed in the third semiconductor layer 103 by laser light irradiation.

According to the method of manufacturing the semiconductor device according to the present embodiment, it is possible to not only adjust the amount of impurities of the second conductivity type to be introduced into a second semiconductor layer 102, but also adjust the amount of impurities of the first conductivity type to be introduced into the third semiconductor layer 103. Furthermore, it is possible to form defects caused by the impurities of the second conductivity type and defects caused by impurities of the first conductivity type after formation of hydrogen donors, so that it is easy to adjust characteristics of a field stop layer and a collector layer.

The invention invented by the inventor of the present invention has been specifically described above based on the embodiments. However, it goes without saying that the present disclosure is not limited to the afore-mentioned embodiments, and can be variously changed without departing from the spirit of the invention.

What is claimed is:

1. A method of manufacturing a semiconductor device, the method comprising:
introducing an impurity having a first conductivity type from an upper surface of a semiconductor substrate having the upper surface and a lower surface;
forming a metal layer on the upper surface;
introducing hydrogen from the lower surface and forming a first semiconductor layer;
performing first heat treatment on the semiconductor substrate, and donating the hydrogen introduced into the first semiconductor layer;
introducing from the lower surface an impurity of a second conductivity type opposite to the first conductivity type, and forming a second semiconductor layer at a position shallower than a position of the first semiconductor layer; and
performing second heat treatment on the semiconductor substrate at a temperature higher than a temperature of the first heat treatment, and applying the second conductivity type to the second semiconductor layer.

2. The method of manufacturing the semiconductor device according to claim 1,
wherein a thickness of the first semiconductor layer after the second heat treatment is larger than a thickness of the second semiconductor layer.

3. The method of manufacturing the semiconductor device according to claim 1,
wherein, after the second heat treatment,
the first semiconductor layer includes a first region that has a maximum value in a carrier concentration distribution in the first semiconductor layer, and
the second semiconductor layer includes a second region that has a carrier concentration distribution lower than the carrier concentration distribution of the first semiconductor layer.

4. The method of manufacturing the semiconductor device according to claim 3,
wherein a minimum value of a hydrogen concentration distribution of the second region is smaller than a setting value of a hydrogen dose amount at a time of the introduction of the hydrogen.

5. The method of manufacturing the semiconductor device according to claim 3,
wherein the carrier concentration distribution of the first semiconductor layer after the second heat treatment has a gradient of a carrier concentration that increases toward a depth direction when the lower surface is set as a reference surface.

6. The method of manufacturing the semiconductor device according to claim 1, further comprising introducing the impurity of the first conductivity type from the lower surface, and forming a third semiconductor layer before the second heat treatment.

7. The method of manufacturing the semiconductor device according to claim 1,
wherein the first heat treatment is performed by a heating furnace, and
wherein the second heat treatment is performed by irradiating the lower surface with laser light.

8. The method of manufacturing the semiconductor device according to claim 7,
wherein a third region in which a defect formed in the semiconductor substrate has been recovered is formed on a side of the lower surface of the semiconductor substrate by performing the second heat treatment using the laser light.

9. The method of manufacturing the semiconductor device according to claim 8,
wherein an irradiation depth of the laser light is larger than or approximately equal to a depth at which the first semiconductor layer is formed when the lower surface is set as a reference surface, and
wherein the third region reaches the second semiconductor layer and the first semiconductor layer in a depth direction for which the lower surface is set as the reference surface.

10. The method of f manufacturing the semiconductor device according to claim 8,
wherein an irradiation depth of the laser light is smaller than a depth at which the second semiconductor layer is formed when the lower surface is set as a reference surface, and
wherein the third region reaches part of the second semiconductor layer in a depth direction for which the lower surface is set as the reference surface.

11. A semiconductor device comprising:
a semiconductor substrate that has an upper surface and a lower surface;
a metal layer that is formed on the upper surface;
an impurity region that is formed on a side of the upper surface and has a first conductivity type;
a first semiconductor layer that is formed on a side of the lower surface, has a first thickness in a direction perpendicular to the lower surface, and contains donated hydrogen; and
a second semiconductor layer that is formed closer to the side of the lower surface than the first semiconductor layer, contains an impurity of a second conductivity type opposite to the first conductivity type, and has a second thickness smaller than the first thickness,
wherein the first semiconductor layer includes a first region that has a maximum value in a carrier concentration distribution in the first semiconductor layer,
wherein the second semiconductor layer includes a second region that has a carrier concentration distribution lower than the carrier concentration distribution of the first semiconductor layer, and
wherein, when the lower surface is set as a reference surface, the first region is located at a position deeper than a position of the second region.

12. The semiconductor device according to claim 11,
wherein the carrier concentration distribution of the first semiconductor layer has a gradient of a carrier concentration that increases toward a depth direction when the lower surface is set as the reference surface.

13. The semiconductor device according to claim 11, further comprising a third semiconductor layer that is formed closer to the side of the lower surface than the second semiconductor layer, and contains an impurity of the first conductivity type.
